(19) United States
(12) Patent Application Publication
(10) Pub. No.: US 2003/0197219 A1
(43) Pub. Date: Oct. 23, 2003

(54) Flash memory device and fabricating method therefor

(76) Inventors: Jong Il Kim, Daejeon (KR); Choong Ho Hwang, Kyoungki-do (KR)

Correspondence Address: LADAS & PARRY, 224 SOUTH MICHIGAN AVENUE, SUITE 1200, CHICAGO, IL, 60604, US

(21) Appl. No.: 10/330,765

(22) Filed: Dec. 27, 2002

(30) Foreign Application Priority Data
Apr. 23, 2002 (KR) 2002-22119

(51) Int. Cl. H01L 29/788

(52) U.S. Cl. 257/316

(57) ABSTRACT

A flash memory device and fabricating method thereof. The fabricating method comprises the steps of: forming a floating gate oxide film on a silicon substrate, forming a floating gate on the floating gate oxide film, forming a control gate oxide film on the floating gate, forming a control gate including slant side surfaces on the control gate oxide film; and the flash memory device comprises: a floating gate oxide film formed on a silicon substrate, a floating gate formed on the floating gate oxide film, a control gate oxide film formed on the floating gate, and a control gate formed on the control gate oxide film and including slant side surfaces.

### BACKGROUND OF THE INVENTION

1. Field of the Invention

The present invention relates to a method for fabricating a flash memory device, more particularly to a flash memory device and fabricating method thereof which is capable of increasing activating characteristics and reliability of the device by improving patterning of a control gate.

2. Description of the Prior Art

Referring to FIGS. 1a and 1b, general activating principles of a flash memory device and Fowler-Nordheim Tunneling (FN Tunneling) phenomenon are explained below.

FIG. 1a is a schematic sectional view of a general stacked gate cell flash memory transistor showing FN tunneling phenomena in the case of programming, and FIG. 1b shows the stacked gate cell flash memory in the case of erasing.

As shown in FIGS. 1a and 1b, as regards the general principles of the flash memory device, programming is carried out through implanting electrons into a floating gate 3 by utilizing the Fowler-Nordheim Tunneling phenomenon, and erasing activity is carried out through discharging the electrons.

Also, according to situations whether electrons are implanted and existed in the floating gate, reading activity of logics 1 or 0 is carried out. The unexplained numeral 1 in the drawing refers to a silicon substrate, the numeral 5 in the drawing refers to a control gate, the numeral 7a refers to a source region, and the numeral 7b refers to a drain region.

Further, according to the Fowler-Nordheim Tunneling phenomenon, which is a kind of quantum mechanical tunneling of electrons, when a energy barrier level is higher than that of electrons, a classic mechanical phenomenon can occur in the quantum mechanics such as electrons may not jump over the barrier thereof, however, although the energy level of electrons is lower than the energy barrier, electrons can pass through the barrier when a high electric field above 10MV/cm is produced by the application of high voltage, or the barrier is very thin. In this case, the high voltage means that it is higher than the gate voltage of 1.8 to 3.3 V, which is employed for the reading activity of a flash memory device.

FIG. 2 is a schematic view of the conventional stacked gate cell flash memory device in section showing conventional patterning of a control gate.

With regard to a conventional method for fabricating a flash memory device as shown in FIG. 2, a floating gate 25 is first formed by depositing a conductive layer for the floating gate on a semiconductor substrate 21 and patterning it, and then a conductive layer for a control gate is deposited on the semiconductor substrate 21 including the floating gate 25, next photoresist materials (not shown) are sprayed on the conductive layer.

Then, a photoresist film pattern 31 is formed by exposing and developing the photoresist materials with photolithography technology and a control gate 29 is formed by patterning of the conductive layer with using the photoresist film pattern as a mask.

However, according to the conventional art as explained above, as side walls of the control gate 29 are thin when they are subjected to conventional etching, effective transfer of the voltages applied can not be achieved.

Further, as shown in FIG. 2, it is difficult to pattern the control gate 29 by way of increasing the length L1 of the mask as noted by “A” in FIG. 2 in order to thicken the side walls of the control gate 29, because the intervals S between the conventional patterns become narrower as noted by “S1”.

Also, if a precious photo process is not secured, symmetries of the right and left in a lower part of the control gate is not achieved due to misalignment of the mask, resulting in reliability problems.

### SUMMARY OF THE INVENTION

Accordingly, the present invention has been made to solve the above-mentioned problems occurring in the prior art, and an object of the present invention is to provide a method for fabricating a flash memory device, which is capable of increasing conservation effects of electrons implanted into a floating gate by a Fowler-Nordheim Tunneling phenomenon and improving reliability of the activity characteristics of the flash memory device.

Another object of the present invention is to provide a method for fabricating a flash memory device, which can easily perform patterning of the memory device, because interactions between neighboring patterns can be reduced by decreasing the size of the mask pattern.

Still another object of the present invention is to provide a method for fabricating a flash memory device, which can minimize the unsymmetrical property of the lower part of the control gate resulting from misalignment of the mask, because contact areas with a silicon substrate can be increased by forming a tail part in the lower part of the control gate.

In order to accomplish these objects, there is provided a method for fabricating a flash memory device comprising the steps of: forming a floating gate oxide film on a silicon substrate, forming a floating gate on the floating gate oxide film, forming a control gate oxide film on the floating gate, forming a control gate including slant side surfaces on the control gate oxide film.

In accordance with another aspect of the present invention, there is also provided a flash memory device comprising: a floating gate oxide film formed on a silicon substrate, a floating gate formed on the floating gate oxide film, a control gate oxide film formed on the floating gate, and a control gate formed on the control gate oxide film and including slant side surfaces.

### BRIEF DESCRIPTION OF THE DRAWINGS

The above and other objects, features and advantages of the present invention will be more apparent from the following detailed description taken in conjunction with the accompanying drawings, in which:

FIG. 1A is a schematic sectional view of a general stacked gate cell flash memory transistor showing FN tunneling phenomenon in the case of programming, and FIG. 1B is a schematic sectional view of a general stacked gate cell flash memory transistor in the case of erasing;

FIG. 2 is a schematic view of the conventional stacked gate cell flash memory device in section showing conventional patterning of the control gate;

FIG. 3 is a sectional view illustrating a method for fabricating a flash memory device in accordance with the present invention;

FIGS. 4A and 4B are sectional views illustrating the flash memory device and fabricating method thereof in accordance with the present invention.

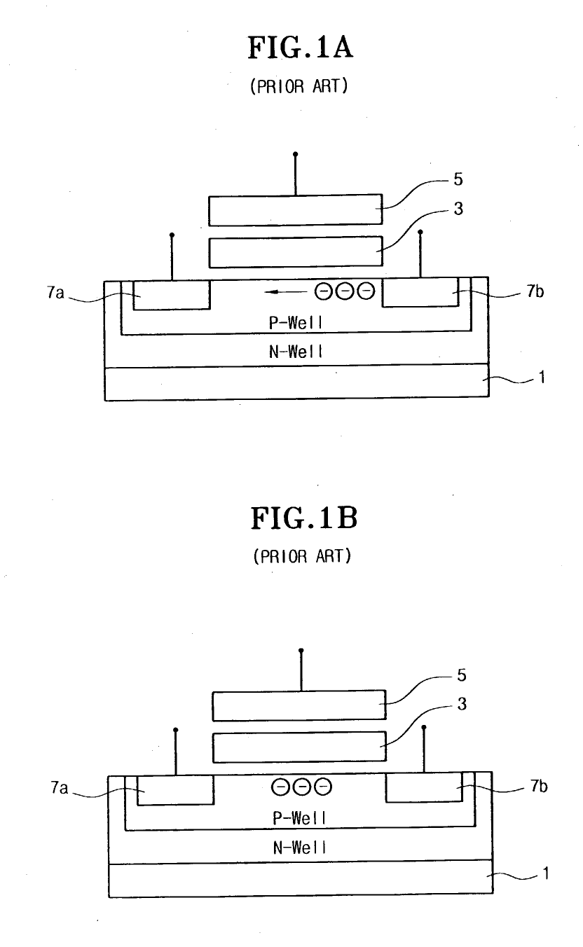

### DETAILED DESCRIPTION OF THE PREFERRED EMBODIMENTS

Hereinafter, a preferred embodiment of the present invention will be described with reference to the accompanying drawings.

FIG. 3 is a sectional view illustrating a flash memory device and fabricating method thereof in accordance with the present invention.

As shown in FIG. 3, in the flash memory device according to the present invention, a floating gate oxide film 43 is formed on a silicon substrate 41, and a floating gate 45 is formed on the oxide film 43.

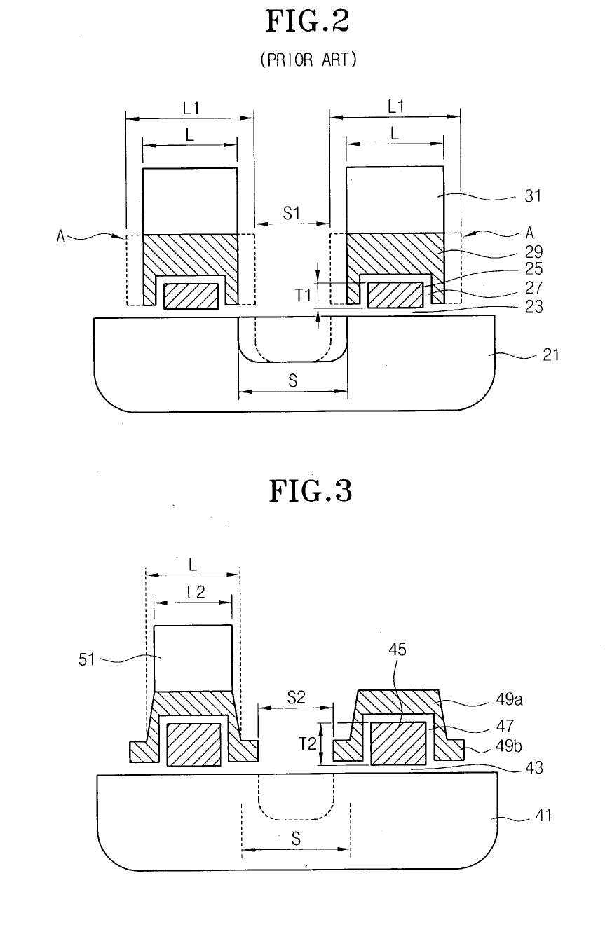

Further, a control gate oxide film 47 is formed on the floating gate 45, and a control gate 49 is formed on the control gate oxide film 47. In this case, side parts 49a of the control gate 49 are formed slantly, and tails 49b are formed on a lower part thereof. Also, a width L2 of a photoresist film pattern 51, which is used to form the control gate 49, is smaller than a conventional width L, and a thickness T2 of the floating gate 45 is increased to one and a half times of a conventional thickness T1 shown in FIG. 2.

A patterning process of the control gate in the flash memory device in accordance with the present invention is explained below.

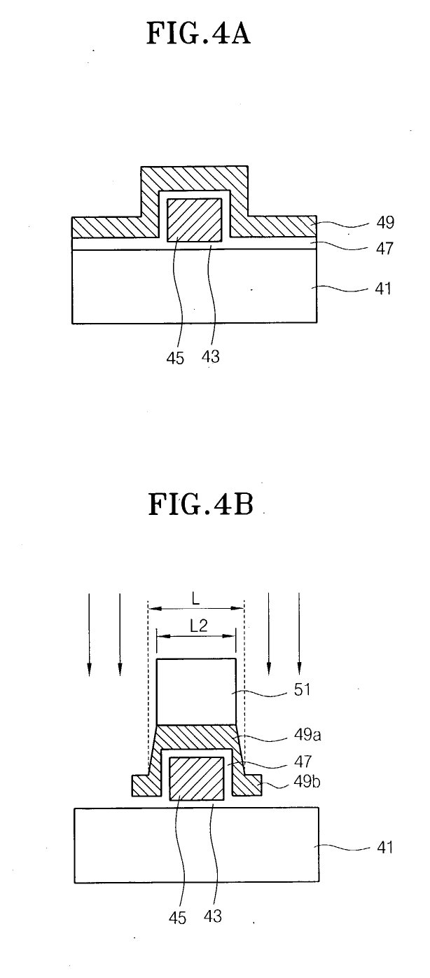

FIGS. 4A and 4B are sectional views illustrating a method for fabricating a flash memory device in accordance with the present invention.

According to the method for fabricating a flash memory device in accordance with the present invention, as shown in FIG. 4A, a floating gate oxide film 43 is formed on a silicon substrate 41, a first polysilicon layer for making floating gate is deposited on the floating gate oxide 43, first photoresist materials are sprayed on the polysilicon layer, exposing and developing processes and selective patterning of the photoresist materials are carried out by employing photolithography technology to produce a first photoresist film pattern (not shown), and then selective patterning of the first polysilicon layer is carried out using the first photoresist film pattern (not shown) as a mask, resulting in production of a floating gate 45. In this case, the first polysilicon layer deposited to form the floating gate 45 is formed thickly to make the side walls of the control gate, which will be made in the following process, thicker than that of the conventional side walls.

Then, a control gate oxide film 47 is deposited on the entire surfaces of the silicon substrate 41 and the floating gate 45 after removing the first photoresist film pattern (not shown), and a second polysilicon layer 49 is deposited on the control gate oxide film to form the control gate.

Next, as shown in FIG. 4B, second photoresist materials are sprayed on the second polysilicon layer 49, and exposing, developing and selective patterning of the photoresist materials are carried out by photolithography technology, resulting in the production of the second photoresist film pattern 51. In this instance, the second photoresist film pattern 51 has a smaller width L2 than the conventional width L.

Subsequently, a control gate 49a with slant side walls is formed by selective patterning of the second polysilicon layer 49 using the second photoresist film pattern 51 as a mask. In this case, tail parts 49b are formed at lower part of the control gate 49b, resulting in increase of the contact areas of the silicon substrate 41.

In accordance with the method for fabricating a flash memory device of the present invention, the following advantages are achieved.

According to the present invention, it is possible to make the width of the photoresist film pattern smaller than that of the conventional case, thereby securing adequate intervals between the neighboring patterns. Also, it is possible to make the side walls of the control gate thicker than the conventional case while the width of the photoresist film pattern is made smaller than that of the conventional case.

Therefore, it is possible to form the side walls of the control gate slant, to deposit films on them, and to etch the deposited films on the slant side walls so that a part of the deposited films remains as tails in the lower part of the control gate.

Also, it is possible to minimize the unsymmetrical property of the lower part in the control gate resulting from the misalignment of the mask. That is, as the area of the lower part is increased in comparison with the conventional case, it is possible to secure minimum areas for activating the flash memory device in spite of some misalignment of the mask.

Further, the characteristics of the flash memory device is improved based on the increase of the thickness of the floating gate and enlargement of the capability of preventing the electrons from tunneling through channels.

Therefore, it is possible to improve the securing effect of the electrons implanted into the floating gate through the Fowler-Nordheim Tunneling phenomenon by increasing the thickness of the floating gate, resulting in improvement of the reliability and characteristics of the flash memory device.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A flash memory device comprising:
a floating gate oxide film formed on a silicon substrate;
a floating gate formed on the floating gate oxide film;
a control gate oxide film formed on the floating gate; and
a control gate formed on the control gate oxide film and including slant side surfaces.

2. The flash memory device according to claim 1, wherein the control gate is formed integrally with upper and side surfaces of the floating gate.

3. The flash memory device according to claim 1, wherein tails are formed on the lower surface of the control gate.

4. A method for fabricating a flash memory device, the method comprising the steps of:
forming a floating gate oxide film on a silicon substrate;
forming a floating gate on the floating gate oxide film;
forming a control gate oxide film on the floating gate;
forming a control gate including slant side surfaces on the control gate oxide film.

5. The method for fabricating a flash memory device according to claim 4, wherein the control gate is formed integrally with upper and side surfaces of the floating gate.

6. The method for fabricating a flash memory device according to claim 4, wherein tails are formed on a lower surface of the control gate.
